(19) United States
(12) Patent Application Publication
(10) Pub. No.: US 2025/0329692 A1
(43) Pub. Date: Oct. 23, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Un-Byoung KANG, Suwon-si (KR); Jiyoung PARK, Suwon-si (KR); Jeonggi JIN, Suwon-si (KR)

(73) Assignee: Samsung Electronics Co., Ltd., Suwon-si (KR)

(21) Appl. No.: 18/950,452

(22) Filed: Nov. 18, 2024

(30) Foreign Application Priority Data
Apr. 23, 2024 (KR) 10-2024-0054107

(51) Int. Cl. H01L 25/065; H01L 23/00; H01L 23/31; H01L 23/538; H01L 25/00

(52) U.S. Cl. CPC H01L 25/0657; H01L 23/3135; H01L 24/16; H01L 24/48; H01L 25/50; H01L 23/538; H01L 2224/16227; H01L 2224/48227; H01L 2225/06562

(57) ABSTRACT

A semiconductor package may include a first semiconductor chip including a first chip pad on an upper surface of the first semiconductor chip, a second semiconductor chip stacked on the first semiconductor chip and including a second chip pad on an upper surface of the second semiconductor chip, an insulating pattern covering a side surface of the first semiconductor chip and having a width that decreases from a lower surface of the first semiconductor chip toward the upper surface of the first semiconductor chip, a conductive post at one side of the second semiconductor chip, the conductive post connected to the first chip pad and extending in a direction perpendicular to the upper surface of the first semiconductor chip, a seed pattern between the first chip pad and the conductive post, and a first connection wire connected to the second chip pad.

### CROSS-REFERENCE TO RELATED APPLICATIONS

This U.S. non-provisional patent application claims priority under 35 U.S.C. § 119 to Korean Patent Application No. 10-2024-0054107, filed on Apr. 23, 2024, in the Korean Intellectual Property Office, the entire contents of which are hereby incorporated by reference.

### BACKGROUND OF THE INVENTION

The inventive concepts relate to a semiconductor package and a method of manufacturing the same.

With the development of the electronics industry, electronic products have increasingly exhibited high performance, high speed, and compact size. To meet the trend, a packaging technology in which a plurality of semiconductor chips are mounted in a single package has been considered.

A semiconductor package is provided to implement an integrated circuit chip to qualify for use in electronic products. In one type of a semiconductor package, a semiconductor chip is mounted on a printed circuit board (PCB) and bonding wires or bumps are used to electrically connect the semiconductor chip to the printed circuit board. With the recent development of electronic industry, the semiconductor package is variously developed to reach the goal of compact size, small weight, and/or low manufacturing cost. In addition, many kinds of semiconductor packages also include, e.g., high-capacity mass storage devices.

A size of semiconductor chip becomes smaller with high integration of the semiconductor chip. For semiconductor chips with small sizes, solder balls may be difficult to adhere, handle, and test. Additionally, when semiconductor chips have various sizes, various mount boards to accommodate such semiconductor chips may be necessary. A fan-out panel level package is proposed to solve these problems as described above.

### SUMMARY

Various example embodiments of the inventive concepts are to provide a semiconductor package with improved structural stability and a method of manufacturing the same.

Various example embodiments of the inventive concepts are to provide a method of manufacturing a semiconductor package with a simple manufacturing process and a semiconductor package manufactured through the same.

The problem to be solved by the inventive concepts are not limited to the problems mentioned above, and other problems not mentioned will be clearly understood by those skilled in the art from the description below.

A semiconductor package according to some example embodiments of the inventive concepts may include a first semiconductor chip including a first chip pad on an upper surface of the first semiconductor chip, a second semiconductor chip stacked on the first semiconductor chip and including a second chip pad on an upper surface of the second semiconductor chip, an insulating pattern covering a side surface of the first semiconductor chip and having a width that decreases from a lower surface of the first semiconductor chip toward the upper surface of the first semiconductor chip, a conductive post at one side of the second semiconductor chip, the conductive post connected to the first chip pad and extending in a direction perpendicular to the upper surface of the first semiconductor chip, a seed pattern between the first chip pad and the conductive post, a first connection wire connected to the second chip pad and extending in a direction perpendicular to the upper surface of the second semiconductor chip, and a molding layer surrounding the first semiconductor chip, the second semiconductor chip, the conductive post, and the first connection wire. An upper surface of the conductive post and an upper end of the first connection wire are exposed on an upper surface of the molding layer.

A semiconductor package according to some example embodiments of the inventive concepts may include a package substrate, a chip stack including semiconductor chips stacked on the package substrate, a molding layer surrounding the chip stack on the package substrate, and external terminals connected to a lower surface of the package substrate. The chip stack is spaced vertically from an upper surface of the package substrate. Each of the semiconductor chips includes a chip pad on a lower surface thereof. The chip stack includes a first semiconductor chip as the lowermost one of the semiconductor chips, a second semiconductor chip as the uppermost one of the semiconductor chips, and a third semiconductor chip between the first semiconductor chip and the second semiconductor chip. The first semiconductor chip is electrically connected to the package substrate through a conductive bump that vertically penetrates the molding layer and connects a first substrate pad of the package substrate and the chip pad of the first semiconductor chip. The second semiconductor chip is electrically connected to the package substrate through a conductive post that vertically penetrates the molding layer and connects a second substrate pad of the package substrate and the chip pad of the second semiconductor chip. The third semiconductor chip is electrically connected to the package substrate through at least one connection wire that vertically penetrates the molding layer and respectively connects a third substrate pad of the package substrate and the chip pad of the third semiconductor chip.

A method of manufacturing a semiconductor package according to some example embodiments of the inventive concepts may include attaching a first semiconductor chip to a carrier substrate, the first semiconductor chip including a first chip pad on an upper surface thereof, forming an insulating pattern surrounding the first semiconductor chip on the carrier substrate, the insulating pattern including an inclined surface connecting an upper surface of the carrier substrate and an upper surface of the first semiconductor chip, forming a seed layer covering the upper surface of the carrier substrate, the inclined surface of the insulating pattern, and the upper surface of the first semiconductor chip, forming a mask layer covering the first semiconductor chip and the seed layer on the carrier substrate, the mask layer including a vertical hole exposing the seed layer above the first chip pad, filling the vertical hole with a conductive material to form a conductive post, removing the mask layer, selectively removing the seed layer using the conductive post as a mask, attaching a second semiconductor chip on the first semiconductor chip such that the second semiconductor chip is spaced horizontally from the first chip pad, the second semiconductor chip including a second chip pad on an upper surface of the second semiconductor chip, bonding a connection wire extending perpendicularly to the second chip pad using a bonding device, forming a molding layer covering the first semiconductor chip, the second semiconductor chip, the conductive post, and the connection wire on the carrier substrate, and performing a thinning process on the molding layer. After the thinning process, an upper surface of the conductive post and the uppermost end of the connection wire are exposed on an upper surface of the molding layer.

### BRIEF DESCRIPTION OF THE DRAWINGS

Various example embodiments will be more clearly understood from the following brief description taken in conjunction with the accompanying drawings. The accompanying drawings represent non-limiting, example embodiments as described herein.

FIG. 1 is a cross-sectional view illustrating a semiconductor package according to various example embodiments of the inventive concepts.

FIG. 2 is an enlarged view of region ‘A’ of FIG. 1.

FIG. 3 is an enlarged view of region ‘B’ of FIG. 1.

FIGS. 4 to 10 are cross-sectional views for explaining semiconductor packages according to various example embodiments of the inventive concepts.

FIGS. 11 to 26 are cross-sectional views for explaining a method of manufacturing a semiconductor package according to various example embodiments of the inventive concepts.

### DETAILED DESCRIPTION

A semiconductor package according to the inventive concepts will be described with reference to the drawings.

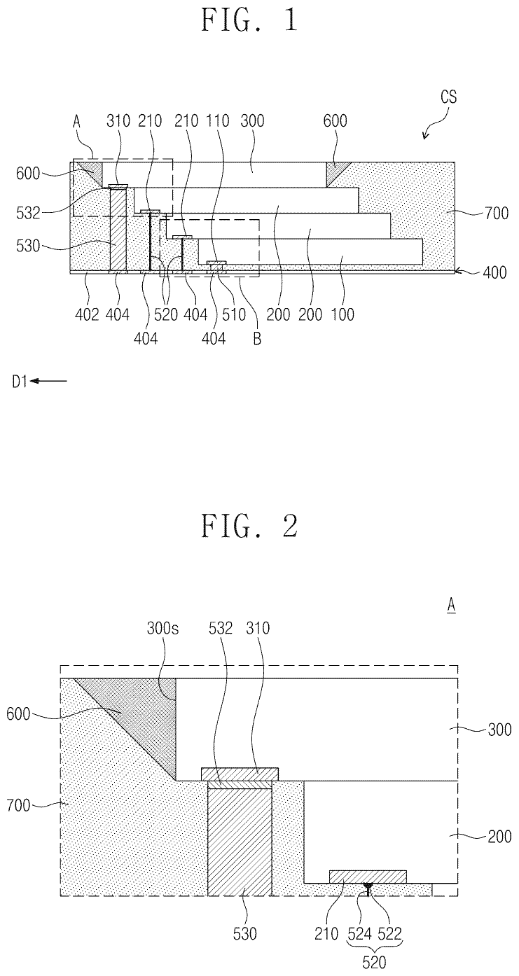

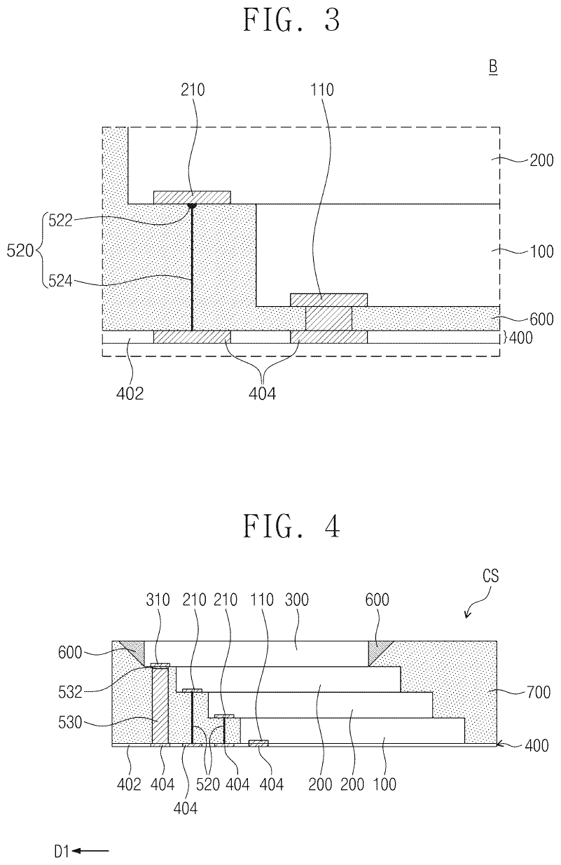

FIG. 1 is a cross-sectional view illustrating a semiconductor package according to various example embodiments of the inventive concepts. FIG. 2 is an enlarged view of region ‘A’ of FIG. 1. FIG. 3 is an enlarged view of region ‘B’ of FIG. 1.

Referring to FIGS. 1 to 3, a semiconductor package may include a chip stack CS.

The chip stack CS may have a plurality of semiconductor chips 100, 200, and 300 stacked on each other in a vertical direction. The semiconductor chip disposed at the lowermost one among the semiconductor chips 100, 200, and 300 of the chip stack CS is referred to as a first semiconductor chip 100, the semiconductor chip disposed at the uppermost one among the semiconductor chips 100, 200, and 300 of the chip stack CS is referred to as a third semiconductor chip 300, and the semiconductor chips disposed between the first semiconductor chip 100 and the third semiconductor chip 300 are referred to as a second semiconductor chip 200. In this specification, the first semiconductor chip 100 and the third semiconductor chip 300 only refer to the semiconductor chips disposed at the lowermost one and the uppermost one of the chip stack CS for convenience of explanation. Although the first to third semiconductor chips 100, 200, and 300 are referred to by different names, it does not mean that they are different semiconductor chips. The first to third semiconductor chips 100, 200, and 300 may include the same semiconductor chip, or may each include different semiconductor chips. For example, the first to third semiconductor chips 100, 200, and 300 may be memory chips such as DRAM, SRAM, MRAM, or flash memory. Alternatively, the first semiconductor chip 100 may be a logic chip, and the second and third semiconductor chips 200 and 300 may be memory chips. Although FIG. 1 shows a chip stack CS having two second semiconductor chips 200, the inventive concepts are not limited thereto. The chip stack CS may have one to four or more second semiconductor chips 200.

The first semiconductor chip 100 may have a front surface and a back surface opposing the front surface. A lower surface of the first semiconductor chip 100 may be the front surface, and an upper surface of the first semiconductor chip 100 may be the back surface. That is, the first semiconductor chip 100 may be placed face down. The first semiconductor chip 100 may have first chip pads 110 provided on the lower surface. The first chip pads 110 may be electrically connected to the integrated circuit of the first semiconductor chip 100.

The second semiconductor chips 200 may be disposed face down on the first semiconductor chip 100. For example, the second semiconductor chips 200 may have a front surface facing the first semiconductor chip 100 and a back surface facing the front surface. That is, a lower surface of the second semiconductor chips 200 may be the front surface, and an upper surface of the second semiconductor chips 200 may be the back surface. Each of the second semiconductor chips 200 may have second chip pads 210 provided on the lower surface thereof. The second chip pads 210 may be electrically connected to the integrated circuit of the second semiconductor chips 200.

The third semiconductor chip 300 may be disposed face down on the uppermost second semiconductor chip 200 among the second semiconductor chips 200. For example, the third semiconductor chip 300 may have a front surface facing the first semiconductor chip 100 and a back surface facing the front surface. That is, a lower surface of the third semiconductor chip 300 may be the front surface, and an upper surface of the third semiconductor chip 300 may be the back surface. The third semiconductor chip 300 may have third chip pads 310 provided on the lower surface thereof. The third chip pads 310 may be electrically connected to the integrated circuit of the third semiconductor chip 300.

FIG. 1 illustrates that each of the first to third semiconductor chips 100, 200, and 300 has one chip pad 110, 210, and 310, but this means that only one chip pad 110, 210, or 310 is illustrated in FIG. 1, which is a cross-sectional view, and each of the first to third semiconductor chips 100, 200, and 300 may include a plurality of chip pads 110, 210, and 310.

The first to third semiconductor chips 100, 200, and 300 may be arranged in an offset stack structure. For example, the first to third semiconductor chips 100, 200, and 300 may be stacked inclined in a first direction D1 parallel to the upper surface of the first semiconductor chip 100, which may be in a form of an upward sloping staircase (e.g., a cascade form). Specifically, each of the first to third semiconductor chips 100, 200, and 300 may protrude in the first direction D1 from the first semiconductor chip 100 or the second semiconductor chips 200 therebelow.

As the first to third semiconductor chips 100, 200, and 300 are stacked in a step shape, a portion of a lower surface of each of the second and third semiconductor chips 200 and 300 may be exposed (hereinafter, referred to as an exposed surface). According to an offset stacking direction of the first to third semiconductor chips 100, 200, and 300, the exposed surfaces of the second and third semiconductor chips 200 and 300 may be disposed adjacent to side surfaces of the second and third semiconductor chips 200 and 300 in the first direction D1. Here, the offset stacking direction is defined as a direction in which semiconductor chips are shifted relative to other semiconductor chips therebelow when stacking. For example, in FIG. 1, the offset stacking direction of the first to third semiconductor chips 100, 200, and 300 may be in the first direction D1. The lower surfaces of the first to third semiconductor chips 100, 200, and 300 may be active surfaces. For example, the first chip pads 110 of the first semiconductor chip 100 may be disposed on the lower surface of the first semiconductor chip 100, the second chip pads 210 of the second semiconductor chips 200 may be disposed on the exposed surface of the lower surface of the second semiconductor chips 200, and the third chip pads 310 of the third semiconductor chip 300 may be provided on the exposed surface of the lower surface of the third semiconductor chip 300. That is, the second chip pads 210 of the second semiconductor chips 200 may be disposed on one side of the first direction D1 from of the first semiconductor chip 100 disposed therebelow or another second semiconductor chip 200 disposed therebelow. The third chip pads 310 of the third semiconductor chip 300 may be disposed on one side in the first direction D1 from the uppermost second semiconductor chip 200.

Although not shown, adhesive layers may be provided on the upper surface of the first semiconductor chip 100, the upper surface of the second semiconductor chips 200, and the upper surface of the third semiconductor chip 300, respectively. The first to third semiconductor chips 100, 200, and 300 may be adhered to other first and second semiconductor chips 100, 200 disposed therebelow using the adhesive layers. That is, the third semiconductor chip 300 may be attached to the uppermost second semiconductor chip 200 using the adhesive layer, the second semiconductor chips 200 may be attached to another semiconductor chip 200 disposed therebelow using the adhesive layers, and the lowermost second semiconductor chip 200 may be attached to the first semiconductor chip 100 using the adhesive layer. The adhesive layers may include die attach film (DAF).

A pad layer 400 may be provided. The pad layer 400 may be disposed below the chip stack CS. The pad layer 400 may be vertically spaced from the chip stack CS. For example, an upper surface of the pad layer 400 and the lower surface of the first semiconductor chip 100 may be spaced apart from each other. The pad layer 400 may be provided for external connection of the first to third semiconductor chips 100, 200, and 300. The pad layer 400 may include an insulating pattern 402 and pads 404 in the insulating pattern 402.

The insulating pattern 402 may include an inorganic insulating layer such as silicon oxide (SiO) or silicon nitride (SiN). Alternatively, the insulating pattern 402 may include a polymer material. However, example embodiments are not limited thereto. The insulating pattern 402 may include insulating polymer or photoimageable dielectric, (PID). For example, the photoimageable dielectric may include at least one of photosensitive polyimide, polybenzoxazole (PBO), phenol-based polymer, or benzocyclobutene-based polymer. However, example embodiments are not limited thereto.

Pads 404 may be provided in the insulating pattern 402. The pads 404 may be exposed on upper and lower surfaces of the insulating pattern 402. When viewed in a plan view, positions of the pads 404 may correspond to the first to third chip pads 110, 210, and 310. The pads 404 may be pads to which vertical connection terminals, which will be described later, are connected. The pads 404 may include a conductive material. For example, the pads 404 may include copper (Cu).

The upper surface of the pad layer 400 may be substantially flat. For example, the upper surface of the insulating pattern 402 and the upper surface of the pads 404 may be coplanar.

The chip stack CS may be mounted on the pad layer 400. That is, vertical connection terminals connecting the first to third chip pads 110, 210, and 310 of the first to third semiconductor chips 100, 200, and 300 and the pads 404 of the pad layer 400 may be provided. The vertical connection terminals may include conductive bumps 510 connecting the first semiconductor chip 100 and the pad layer 400, connection wires 520 connecting the second semiconductor chips 200 and the pad layer 400, and conductive posts 530 connecting the third semiconductor chip 300 and the pad layer 400.

The conductive bumps 510 may be provided on the lower surface of the first semiconductor chip 100. The first semiconductor chip 100 may be mounted on the pad layer 400 using the conductive bumps 510. The conductive bumps 510 may be disposed on the first chip pads 110 of the first semiconductor chip 100. The conductive bumps 510 may be connected to lower surfaces of the first chip pads 110. The conductive bumps 510 may be connected to the upper surfaces of the pads 404 of the pad layer 400. That is, each of the conductive bumps 510 may connect one of the first chip pads 110 and one of the pads 404. The conductive bumps 510 may include solder bumps.

The connection wires 520 may be provided on the lower surfaces of the second semiconductor chips 200. The connection wires 520 may be disposed on one side of the first semiconductor chip 100 in the first direction D1. The second semiconductor chips 200 may be mounted on the pad layer 400 using the connection wires 520. Specifically, the connection wires 520 may directly connect the second chip pads 210 of the second semiconductor chips 200 and the pads 404 of the pad layer 400.

As shown in FIG. 2, the connection wires 520 may be bonded to the second chip pads 210 using a stitch bonding method or a ball bonding method. For example, each of the connection wires 520 may include a bonding portion 522 adhered to the lower surface of the second chip pads 210, and a wire loop 524 extending from the bonding portion 522. The bonding portion 522 may have a ball shape or a folded shape. However, example embodiments are not limited thereto. A width of the bonding portion 522 may be larger than a width of the wire loop 524.

As shown in FIG. 3, the connection wires 520 may be directly connected to pads 404. For example, one end of the wire loop 524 of the connection wires 520 may be directly connected to the upper surface of the pads 404.

The connection wires 520 may extend from the lower surface of the second chip pads 210 to the upper surface of the pads 404, and all of the connection wires 520 may be disposed between the lower surface of the second semiconductor chip 200 and the upper surface of the pad layer 400. An angle between the connection wires 520 and the upper surface of the pads 404 or the lower surface of the second chip pads 210 may be about 80 degrees to about 90 degrees. Preferably, the angle between the connection wires 520 and the upper surface of the pads 404 or the lower surface of the second chip pads 210 may be 90 degrees. That is, the connection wires 520 may extend vertically from the upper surface of the pads 404. The connection wires 520 may extend vertically from the lower surfaces of the second chip pads 210.

The conductive posts 530 may be provided on the lower surface of the third semiconductor chip 300. The third semiconductor chip 300 may be mounted on the pad layer 400 using conductive posts 530. The conductive posts 530 may be disposed on the third chip pads 310 of the third semiconductor chip 300. The conductive posts 530 may be electrically connected to the lower surfaces of the third chip pads 310. The conductive posts 530 may be connected to the upper surfaces of the pads 404 of the pad layer 400. That is, each of the conductive posts 530 may connect one of the third chip pads 310 and one of the pads 404. The conductive posts 530 may have a vertically extending pillar shape. A width of the conductive posts 530 may be larger than a width of the connection wires 520. The width of the conductive posts 530 may be constant depending on the vertical level, or may decrease toward the third chip pads 310. The conductive posts 530 may include copper (Cu) or tungsten (W). However, example embodiments are not limited thereto.

Seed patterns 532 may be interposed between the conductive posts 530 and the third chip pads 310. The seed patterns 532 may be connected to the lower surfaces of the third chip pads 310. The conductive posts 530 may be connected to the lower surfaces of the seed patterns 532. A width of the seed patterns 532 may be the same as a width of the conductive posts 530. Side surfaces of the seed patterns 532 may be vertically aligned with side surfaces of the conductive posts 530. When the width of the conductive posts 530 is smaller than the width of the third chip pads 310, a portion of the lower surface of the third chip pads 310 may be exposed without being covered by the seed patterns 532. The seed patterns 532 may include a metal material such as gold (Au).

The chip stack CS may further include an insulating pattern 600. The insulating pattern 600 may be disposed on a side surface 300s of the third semiconductor chip 300. The insulating pattern 600 may cover the entire side surface 300s of the third semiconductor chip 300. The insulating pattern 600 may surround the third semiconductor chip 300 when viewed in a plan view. A cross-sectional shape of the insulating pattern 600 may include a triangle. More specifically, a cross section of the insulating pattern 600 may be triangular, one side of which is in contact with the side surface 300s of the third semiconductor chip 300. A width of the insulating pattern 600 may become smaller as the insulating pattern 600 approaches the pad layer 400. The lowermost end of the insulating pattern 600 may be positioned at the same level as the lower surface of the third semiconductor chip 300. The lowermost end of the insulating pattern 600 may be in contact with the lower surface of the third semiconductor chip 300. An upper surface of the insulating pattern 600 may be positioned at the same level as the upper surface of the third semiconductor chip 300. The upper surface of the insulating pattern 600 may be coplanar with the upper surface of the third semiconductor chip 300. That is, the insulating pattern 600 may include a side surface in contact with the side 300s of the third semiconductor chip 300, an upper surface that is coplanar with the upper surface of the third semiconductor chip 300, and an inclined surface connecting the side surface and the upper surface. The insulating pattern 600 may include an insulating material. As an example, the insulating pattern 600 may include an underfill material. The insulating pattern 600 may include epoxy resin.

A molding layer 700 may be provided on the pad layer 400. The molding layer 700 may bury the chip stack CS on the upper surface of the pad layer 400. The molding layer 700 may surround the chip stack CS and expose the upper surface of the chip stack CS. An upper surface of the molding layer 700 may be coplanar with the upper surface of the chip stack CS (e.g., the upper surface of the third semiconductor chip 300 and the upper surface of the insulating pattern 600). The upper surface of the molding layer 700 may be coplanar with the upper surface of the third semiconductor chip 300 and the upper surface of the insulating pattern 600. The molding layer 700 may fill a space between the pad layer 400 and the chip stack CS. That is, the chip stack CS may be spaced apart from the pad layer 400 with the molding layer 700 interposed therebetween. The first semiconductor chip 100 may be spaced apart from the pad layer 400 with the molding layer 700 interposed therebetween. The molding layer 700 may cover the lower surface of the first semiconductor chip 100. The molding layer 700 may surround the conductive bumps 510, the connection wires 520, and the conductive posts 530 between the chip stack CS and the pad layer 400.

According to various example embodiments of the inventive concepts, the second semiconductor chips 200 may be connected to the pad layer 400 using the connection wires 520. In this case, the lowermost first semiconductor chip 100 may be connected to and supported on the pad layer 400 using the conductive bumps 510, and the uppermost third semiconductor chip 300 may be connected to and supported on the pad layer 400 using the conductive posts 530. That is, the chip stack CS may be firmly supported by the conductive bumps 510 and the conductive posts 530, and structural stability may be improved. Additionally, the second semiconductor chips 200 disposed between the first semiconductor chip 100 and the third semiconductor chip 300 may be connected to the pad layer 400 using thin connection wires 520, and a semiconductor package with improved integration may be provided.

In the following example embodiments, the same reference numerals are used for components described in FIGS. 1 to 3, and for convenience of explanation, descriptions thereof are omitted or briefly explained. That is, the description will focus on the differences between the example embodiments of FIGS. 1 to 3 and the various example embodiments described below.

FIG. 4 is a cross-sectional view for explaining a semiconductor package according to various example embodiments of the inventive concepts.

Referring to FIG. 4, the first semiconductor chip 100 of the chip stack CS may not have conductive bumps 510.

The chip stack CS may be in contact with the pad layer 400. More specifically, a lower surface of the chip stack CS, that is, a lower surface of the first semiconductor chip 100, may be in contact with an upper surface of the pad layer 400. On an interface between the first semiconductor chip 100 and the pad layer 400, the first chip pads 110 of the first semiconductor chip 100 may be in contact with the pads 404 of the pad layer 400. That is, the first chip pads 110 of the first semiconductor chip 100 may be directly connected to the pads 404 without conductive bumps.

A molding layer 700 may be provided on the pad layer 400. The molding layer 700 may bury and surround the chip stack CS on the upper surface of the pad layer 400. The molding layer 700 may surround the chip stack CS and expose the upper surface of the chip stack CS. The molding layer 700 may surround the first semiconductor chip 100, the second semiconductor chip 200, the third semiconductor chip 300, the conductive bumps 510, the connection wires 520, and the conductive posts 530, on the pad layer 400.

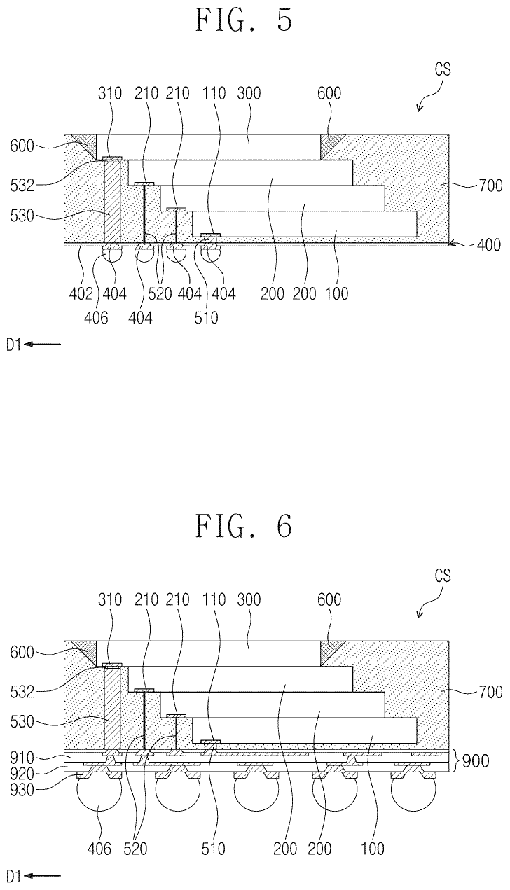

FIG. 5 is a cross-sectional view for explaining a semiconductor package according to various example embodiments of the inventive concepts.

Referring to FIG. 5, a pad layer 400 may be provided. The pad layer 400 may be disposed below the chip stack CS. The pad layer 400 may be vertically spaced from the chip stack CS. The pad layer 400 may be provided for external connection of the first to third semiconductor chips 100, 200, and 300. The pad layer 400 may include an insulating pattern 402 and pads 404 in the insulating pattern 402. The pads 404 may be pads provided with external connection terminals 406.

Pads 404 may be provided in the insulating pattern 402. The pads 404 may have a damascene structure. For example, the pads 404 may have a head portion and a tail portion integrally connected to each other. The head portion may be a wiring portion or a pad portion that horizontally extends a wiring in the pad layer 400. The tail portion may be a via portion that vertically connects the wiring in the pad layer 400. The pads 404 may have an inverted ‘T’ shaped cross section. The head portion of the pads 404 may be provided on a lower surface of the insulating pattern 402, and the tail portion of the pads 404 may extend from an upper surface of the head portion into the insulating pattern 402. Some of the head portions of the pads 404 may correspond to pads of the pad layer 400. For example, a portion of the head portion of the pads 404 may be disposed on a lower surface of the insulating pattern 402. That is, the pads 404 may protrude onto the lower surface of the insulating pattern 402. The conductive bumps 510, the connection wires 520, and the conductive posts 530 may be connected to an upper surface of the tail portion of the pads 404.

External connection terminals 406 may be provided on the lower surface of the pad layer 400. The external connection terminals 406 may include solder balls, solder bumps, or solder pads. Depending on a type of external connection terminals 406, the pad layer 400 may include a ball grid array (BGA), a fine ball-grid array (FBGA), or a land grid array (LGA). However, example embodiments are not limited thereto.

FIG. 6 is a cross-sectional view for explaining a semiconductor package according to various example embodiments of the inventive concepts.

Referring to FIG. 6, a package substrate may include a package substrate 900 instead of the pad layer 400.

The package substrate 900 may be a redistribution substrate. For example, the package substrate 900 may include at least two substrate wiring layers stacked on each other. In this specification, a substrate wiring layer may refer to a wiring layer formed by patterning one insulating material layer and one conductive material layer, respectively. That is, the conductive patterns in one substrate wiring layer may be horizontally extending wirings and may not overlap each other vertically. Each of the substrate wiring layers may include substrate insulation patterns 910 and substrate wiring patterns 920 in the substrate insulation patterns 910. The substrate wiring patterns 920 of one substrate wiring layer may be electrically connected to the substrate wiring patterns 920 of another adjacent substrate wiring layer.

The substrate insulating patterns 910 may include an inorganic insulating layer such as silicon oxide (SiO) or silicon nitride (SiN). Alternatively, the substrate insulation patterns 910 may include a polymer material. However, example embodiments are not limited thereto. The substrate insulation patterns 910 may include insulating polymer or photoimageable dielectric (PID). For example, the photosensitive polymer may include at least one of photosensitive polyimide, polybenzoxazole (PBO), phenol-based polymer, or benzocyclobutene-based polymer. However, example embodiments are not limited thereto.

The substrate wiring patterns 920 may be provided in the substrate insulating patterns 910. The substrate wiring patterns 920 may have a damascene structure. For example, the substrate wiring patterns 920 may have a head portion and a tail portion that are integrally connected to each other. The head portion may be a wiring portion or a pad portion that horizontally extends the wiring in the package substrate 900. The tail portion may be a via portion that vertically connects the wiring in the package substrate 900. The substrate wiring patterns 920 may have an inverted ‘T’ shaped cross section. In each substrate wiring layer, the head portion of the substrate wiring patterns 920 may be disposed on a lower surface of the substrate insulating patterns 910. In each substrate wiring layer, the tail portion of the substrate wiring patterns 920 may extend from an upper surface of the head portion, may penetrate the substrate insulating patterns 910, and may be connected to the head portion of the other substrate wiring patterns 920. The upper surface of the tail portion of the uppermost substrate wiring patterns 920 may be exposed on the upper surface of the substrate insulating patterns 910 of the uppermost substrate wiring layer among the substrate wiring layers. The substrate wiring patterns 920 may include a conductive material. For example, the substrate wiring patterns 920 may include copper (Cu). However, example embodiments are not limited thereto. The substrate wiring patterns 920 may redistribute the semiconductor chips 100, 200, and 300 of the chip stack CS mounted on the package substrate 900.

The tail portion of the substrate wiring patterns 920 of the uppermost substrate wiring layer among the substrate wiring layers may be exposed on the upper surface of the uppermost substrate insulation pattern 910, and the conductive bumps 510, the connection wires 520, and the conductive posts 530 may be connected to the tail portion of the exposed substrate wiring patterns 920. The uppermost substrate wiring patterns 920 may be connected to the lower surfaces of the conductive bumps 510, the lower surfaces of the connection wires 520, and the lower surfaces of the conductive posts 530. Alternatively, pads to which the conductive bumps 510, the connection wires 520, and the conductive posts 530 are connected may be separately provided on the uppermost substrate wiring layer, and the uppermost substrate wiring patterns 920 may penetrate the uppermost substrate insulating pattern 910 to be connected to the pads.

The semiconductor package may have a fan-out structure due to the package substrate 900. The substrate wiring patterns 920 may be connected to external pads 930 disposed on the lower surface of the package substrate 900. The external pads 930 may be pads on which the external connection terminals 406 are disposed. The external pads 930 may penetrate the lowermost substrate insulating pattern 910 and be connected to the substrate wiring patterns 920. Although not shown, a protective layer may be disposed on the lower surface of the package substrate 900. The protective layer may cover the substrate insulating pattern 910 and the substrate wiring patterns 920 and may expose external pads 930. The protective layer may include insulating polymer such as epoxy polymer, Ajinomoto build-up film (ABF), an organic material, or an inorganic material. However, example embodiments are not limited thereto.

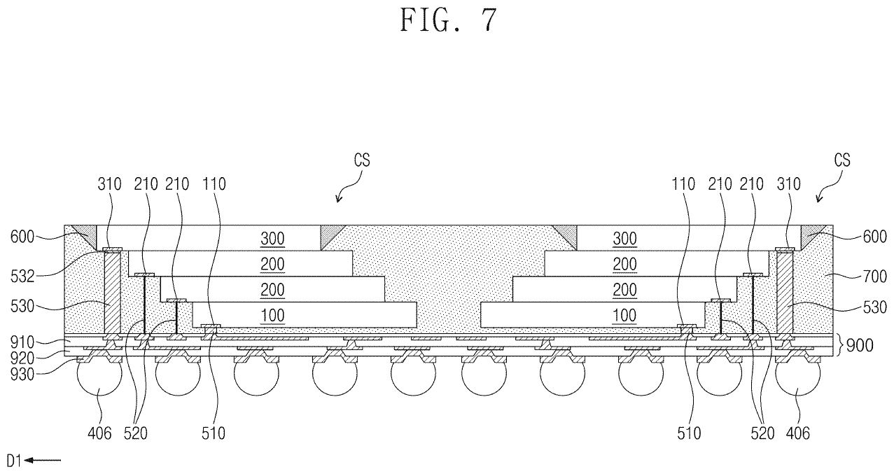

FIG. 7 is a cross-sectional view for explaining a semiconductor package according to various example embodiments of the inventive concepts.

Referring to FIG. 7, at least a plurality of chip stacks CS may be provided on a pad layer 400. Although two chip stacks CS are shown in FIG. 7, the inventive concepts are not limited thereto. Three or more chip stacks CS may be provided.

An offset stacking direction of each chip stack CS may be different. The offset stacking direction of each chip stack CS may be variously changed depending on an arrangement of the pads 404 of the pad layer 400 and an arrangement of the first, second, and third chip pads 110, 210, and 310 of the chip stacks CS. For example, as shown in FIG. 7, the offset stacking direction of the chip stack CS disposed in the first direction D1 may be the first direction D1. According to the offset stacking direction of the first to third semiconductor chips 100, 200, and 300, an exposed surface of the second semiconductor chips 200 may be disposed adjacent to a side surface of the second semiconductor chips 200 in the first direction D1. According to the offset stacking direction of the first to third semiconductor chips 100, 200, and 300, an exposed surface of the third semiconductor chip 300 may be disposed adjacent to a side surface of the third semiconductor chip 300 in the first direction D1. The offset stacking direction of the chip stack CS disposed in a direction opposite to the first direction D1 may be opposite to the first direction D1. According to the offset stacking direction of the first to third semiconductor chips 100, 200, and 300, an exposed surface of the second semiconductor chips 200 may be disposed adjacent to a side surface of the second semiconductor chips 200 in a direction opposite to the first direction D1. According to the offset stacking direction of the first to third semiconductor chips 100, 200, and 300, an exposed surface of the third semiconductor chip 300 may be disposed adjacent to a side surface of the third semiconductor chip 300 in a direction opposite to the first direction D1. However, the offset stacking direction of the chip stacks CS shown in FIG. 7 is only an example, and according to various example embodiments of the inventive concepts, the offset stacking direction of the chip stacks CS may be provided in various ways as needed.

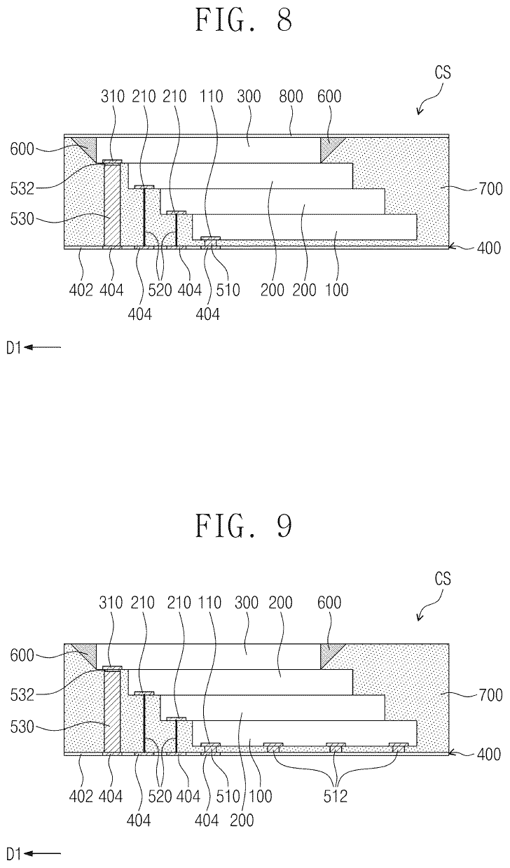

FIG. 8 is a cross-sectional view for explaining a semiconductor package according to various example embodiments of the inventive concepts.

Referring to FIG. 8, a semiconductor package may further include a protective layer 800.

The protective layer 800 may be provided on the molding layer 700. The protective layer 800 may cover an upper surface of the molding layer 700, an upper surface of the insulating pattern 600, and an upper surface of the third semiconductor chip 300. The protective layer 800 may protect the chip stack CS, particularly the third semiconductor chip 300, from external shock. The protective layer 800 may include insulating polymer.

FIG. 9 is a cross-sectional view for explaining a semiconductor package according to various example embodiments of the inventive concepts.

Referring to FIG. 9, a first semiconductor chip 100 may further include dummy bumps 512. The dummy bumps 512 may be disposed on a lower surface of the first semiconductor chip 100. The dummy bumps 512 may be in contact with a lower surface of the first semiconductor chip 100. The dummy bumps 512 may be spaced apart from the first chip pads 110. The dummy bumps 512 may be electrically insulated from the integrated circuit of the first semiconductor chip 100. A height of the dummy bumps 512 may be substantially the same as a height of the conductive bumps 510. The dummy bumps 512 may be in contact with an upper surface of the pad layer 400. Accordingly, the first semiconductor chip 100 and the chip stack CS including the first semiconductor chip 100 may be supported on the pad layer 400 by the dummy bumps 512. In other words, a semiconductor package with improved structural stability may be provided. When the semiconductor package includes a package substrate 900 (refer to FIG. 6) rather than a pad layer 400, dummy bumps 512 may be in contact with an upper surface of the package substrate. The dummy bumps 512 may include solder bumps.

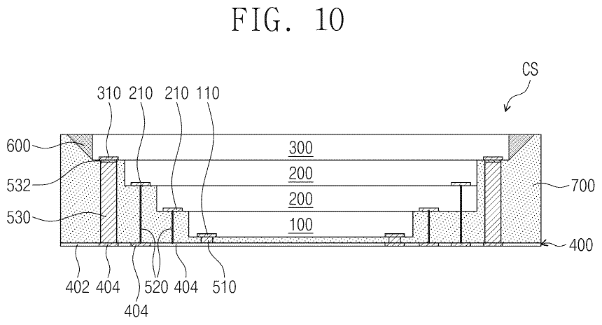

FIG. 10 is a cross-sectional view for explaining a semiconductor package according to various example embodiments of the inventive concepts.

FIGS. 1 to 8 illustrate that the chip stack CS includes semiconductor chips 100, 200, and 300 of the same size, but the inventive concepts are not limited thereto.

Referring to FIG. 10, a chip stack CS may have a plurality of semiconductor chips 100, 200, and 300 stacked on each other in a vertical direction. The lowermost semiconductor chip among the semiconductor chips 100, 200, and 300 of the chip stack CS is referred to as a first semiconductor chip 100, and the uppermost semiconductor chip among the semiconductor chips 100, 200, and 300 of the chip stack CS is referred to as the third semiconductor chip 300, and the semiconductor chips placed between the first semiconductor chip 100 and the third semiconductor chip 300 are referred to as the second semiconductor chip 200.

A width of the first to third semiconductor chips 100, 200, and 300 may be larger as the first to third semiconductor chips 100, 200, and 300 are disposed further away from the pad layer 400. Each of the first to third semiconductor chips 100, 200, and 300 may expose both ends of the other second semiconductor chip 200 or third semiconductor chip 300 disposed on the uppermost one of the first to third semiconductor chips 100, 200, and 300. That is, the first to third semiconductor chips 100, 200, and 300 may be stacked in an inverted pyramid shape. Alternatively, each of the first to third semiconductor chips 100, 200, and 300 may expose only one end of the other second semiconductor chip 200 or the third semiconductor chip 300 disposed on the uppermost one of the first to third semiconductor chips 100, 200, and 300, and other ends of the first and third semiconductor chips 100, 200, and 300 may be aligned with each other. Due to the structures described above, a portion of the lower surface of each of the second semiconductor chips 200 and the third semiconductor chip 300 may be exposed. In addition, each of the first to third semiconductor chips 100, 200, and 300 may expose the chip pads 210 and 310 of the other second semiconductor chip 200 or the third semiconductor chip 300 disposed thereon. Positions of the first to third chip pads 110, 210, and 310 may correspond to the pads 404 of the pad layer 400.

The chip stack CS may be mounted on the pad layer 400. That is, the first to third semiconductor chips 100, 200, and 300 may be electrically connected to the pad layer 400. For example, vertical connection terminals connecting the first to third chip pads 110, 210, and 310 of the first to third semiconductor chips 100, 200, and 300 and the pads 404 of the pad layer 400 may be provided. The vertical connection terminals include conductive bumps 510 connecting the first semiconductor chip 100 and the pad layer 400, connection wires 520 connecting the second semiconductor chips 200 and the pad layer 400, and conductive posts 530 connecting the third semiconductor chip 300 and the pad layer 400.

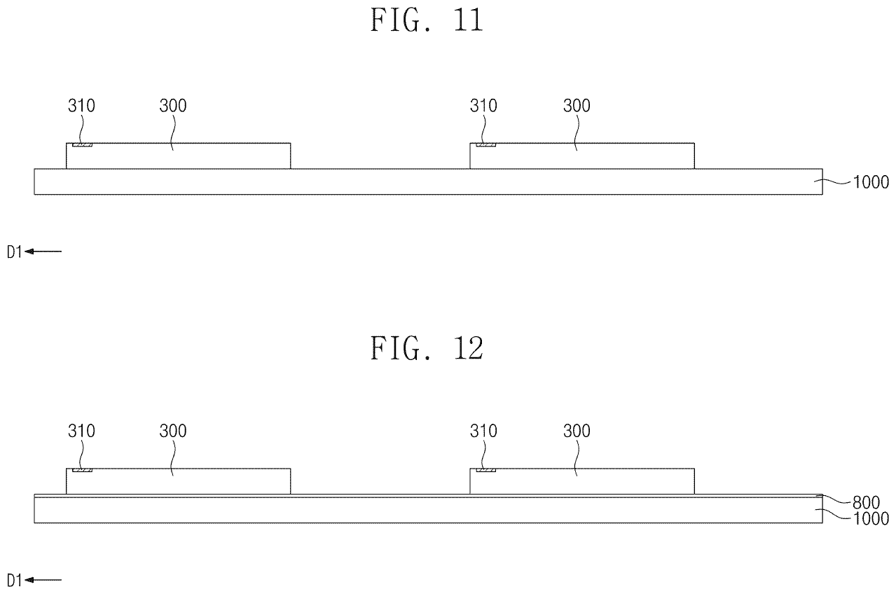

FIGS. 11 to 26 are cross-sectional views for explaining a method of manufacturing a semiconductor package according to various example embodiments of the inventive concepts.

Referring to FIG. 11, a carrier substrate 1000 may be provided. The carrier substrate 1000 may be an insulating substrate containing glass or polymer, or a conductive substrate containing metal. However, example embodiments are not limited thereto. Although not shown, the carrier substrate 1000 may be provided with an adhesive member on an upper surface of the carrier substrate 1000. As an example, the adhesive member may include an adhesive tape.

Third semiconductor chips 300 may be attached to the carrier substrate 1000 using the adhesive member. The third semiconductor chips 300 may be arranged face up. That is, a back surface (i.e., inactive side) of the third semiconductor chips 300 may face the carrier substrate 1000, and third chip pads 310 of the third semiconductor chips 300 may face the carrier substrate 1000.

According to other example embodiments, as shown in FIG. 12, before the third semiconductor chips 300 are attached to the carrier substrate 1000, a protective layer 800 may be attached to the carrier substrate 1000. The protective layer 800 may cover the entire upper surface of the carrier substrate 1000. Thereafter, the third semiconductor chips 300 may be attached or placed on an upper surface of the protective layer 800. In this case, the semiconductor package described with reference to FIG. 8 may be manufactured. Hereinafter, the description will continue based on the results of FIG. 11.

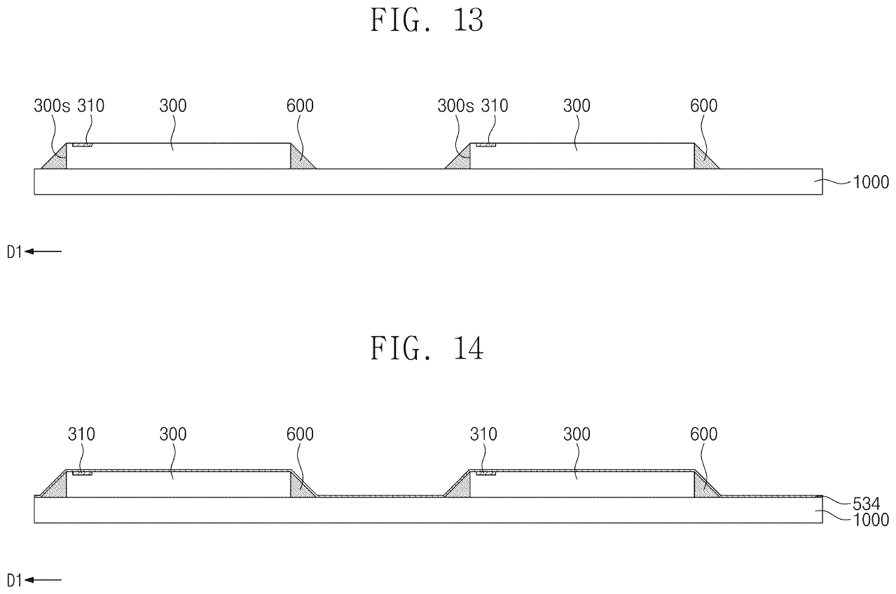

Referring to FIG. 13, insulating patterns 600 may be formed on the carrier substrate 1000. For example, insulating patterns 600 may be formed by injecting an insulating material between the upper surface of the carrier substrate 1000 and side surfaces 300s of the third semiconductor chips 300. The insulating patterns 600 may be formed on the side surfaces 300s of the third semiconductor chips 300. The insulating patterns 600 may cover side surfaces 300s of the third semiconductor chips 300. The insulating patterns 600 may surround the third semiconductor chips 300 when viewed in a plan view. The insulating patterns 600 may fill a space between the upper surface of the carrier substrate 1000 and the side surfaces 300s of the third semiconductor chips 300. More specifically, a cross-section of the insulating patterns 600 may be triangular in contact with the upper surface of the carrier substrate 1000 and the side surfaces 300s of the third semiconductor chips 300. A width of the insulating patterns 600 may increase as the insulating pattern 600 approaches the carrier substrate 1000. The insulating patterns 600 may have an inclined surface connecting an upper surface of the three semiconductor chips 300 and the upper surface of the carrier substrate 1000.

Referring to FIG. 14, a seed layer 534 may be formed on the carrier substrate 1000. The seed layer 534 may conformally cover the upper surface of the carrier substrate 1000, an inclined surfaces of the insulating patterns 600, and the upper surfaces of the third semiconductor chips 300, on the carrier substrate 1000.

According to various example embodiments of the inventive concepts, depending on a shape of the third semiconductor chips 300, the third semiconductor chips 300 and the carrier substrate 1000 may have a step. However, as the insulating patterns 600 having the inclined surface formed on the side surfaces 300s of the third semiconductor chips 300, it may be easy to form the seed layer 534 on the carrier substate 1000 and the third semiconductor chips 300. For example, an empty space may not be formed between the seed layer 534 and the side surfaces 300s of the third semiconductor chips 300 or between the seed layer 534 and the upper surface of the carrier substrate 1000. Accordingly, a method of manufacturing a semiconductor package with less occurrence of defects may be provided.

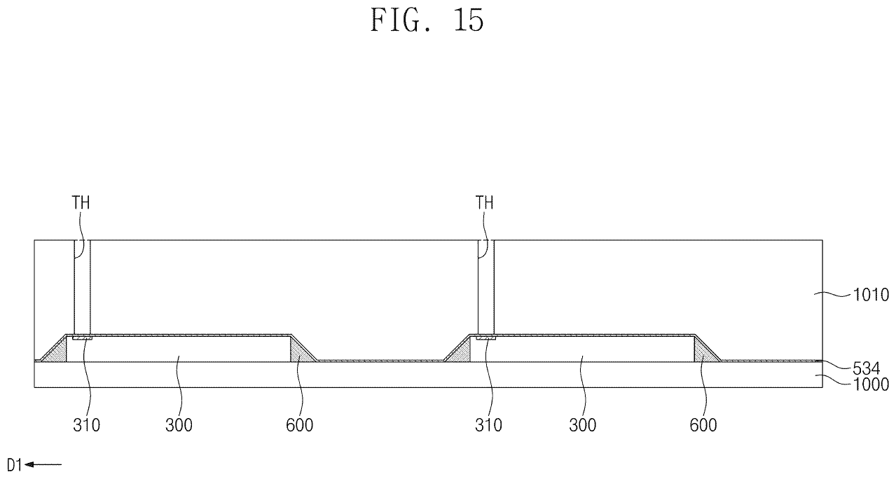

Referring to FIG. 15, a sacrificial layer 1010 may be formed on the carrier substrate 1000. The sacrificial layer 1010 may cover the third semiconductor chips 300, the insulating patterns 600, and the seed layer 534 on the carrier substrate 1000.

The sacrificial layer 1010 may be patterned to form through holes TH exposing the seed layer 534. The through holes TH may be disposed on each of third chip pads 310. Bottom surfaces of the through holes TH may expose an upper surface of the seed layer 534.

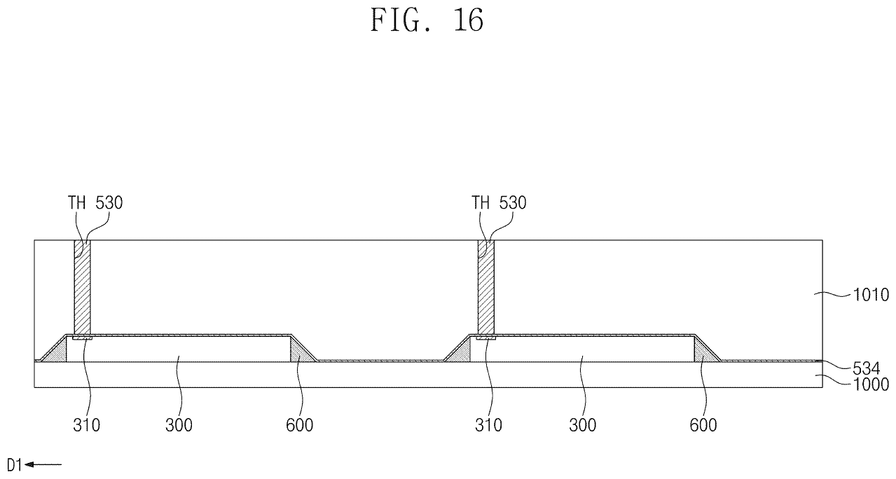

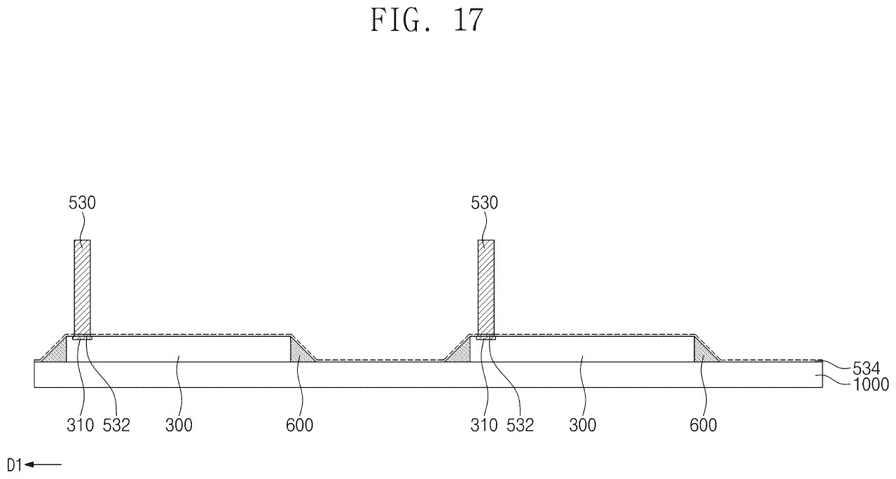

Referring to FIG. 16, conductive posts 530 may be formed on the third semiconductor chips 300. For example, the seed layer 534 exposed by the through holes TH may be subjected to a plating process using the seed layer to form conductive posts 530 that fill the through holes TH.

Referring to FIG. 17, the sacrificial layer 1010 may be removed. The sacrificial layer 1010 may be removed to expose the seed layer 534.

The seed layer 534 may be patterned by performing a patterning process to selectively remove portions of the seed layer 534, using the conductive posts 530 as a mask. The seed layer 534 may be patterned to form remaining seed patterns 532 below the conductive posts 530. The conductive posts 530 may be connected to the third chip pads 310 through seed patterns 532.

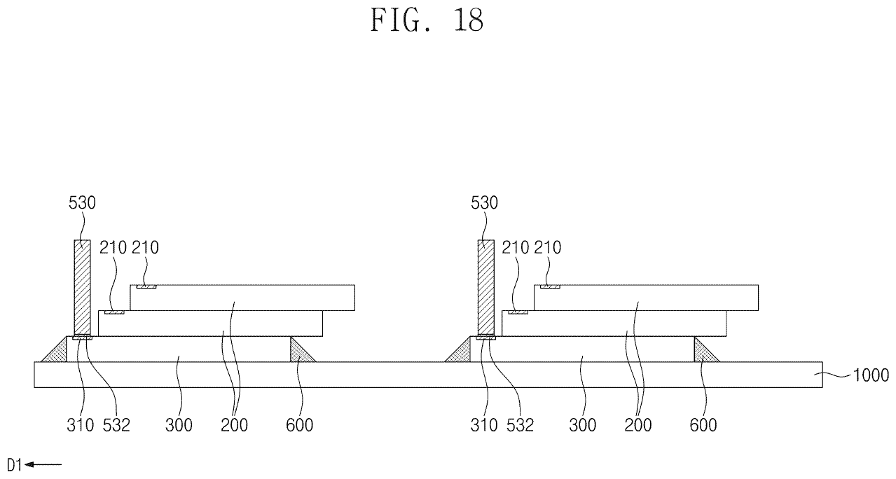

Referring to FIG. 18, second semiconductor chips 200 may be stacked on the third semiconductor chips 300. Based on one third semiconductor chip 300, the second semiconductor chip 200 may be attached to the third semiconductor chip 300 using an adhesive layer, and another second semiconductor chip 200 may be attached to the second semiconductor chip 200 using an adhesive layer. The second semiconductor chips 200 may be arranged face up. That is, the back surfaces of the second semiconductor chips 200 may face the carrier substrate 1000, and the second chip pads 210 of the second semiconductor chips 200 may be disposed to face the carrier substrate 1000. The third semiconductor chip 300 and the second semiconductor chips 200 may be stacked to be shifted from each other in a direction opposite to a first direction D1 parallel to the upper surface of the carrier substate 1000.

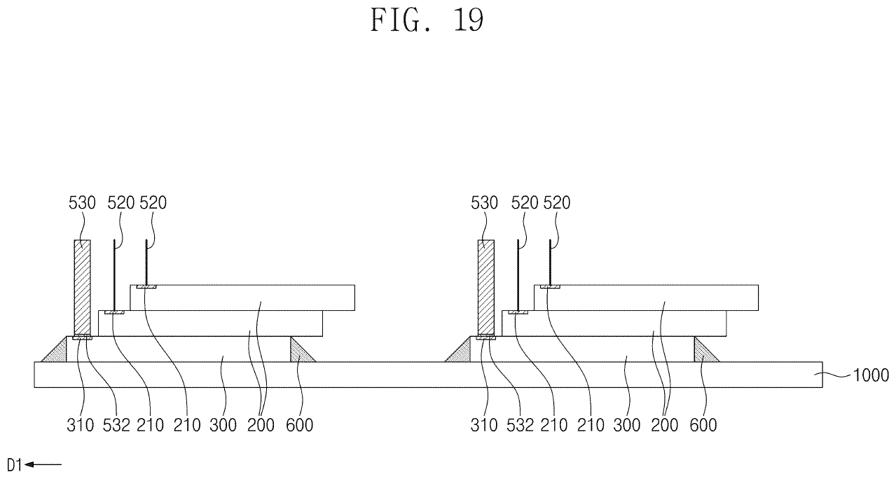

Referring to FIG. 19, connection wires 520 may be formed on each of the second chip pads 210. The connection wires 520 may be formed through, for example, a metal wire bonding process. The metal wire bonding process may include, for example, coupling a metal wire to a bonding device, such as a capillary, placing the metal wire on the second chip pads 210, lowering the capillary to attach a bonding portion 522 (refer to FIG. 2) of a metal wire to the second chip pads 210, raising the capillary to tension the metal wire in a vertical direction from the bonding portion 522 to form a wire loop 524, and cutting the metal wire. During the bonding process between the metal wire and the second chip pad 210, a ball-shaped bonding portion 522 of FIG. 2 may be formed, and even when stretched vertically, at least a portion of the metal wire may have a curved shape. A diameter of the connection wires 520 may be 30 um or less.

According to various example embodiments of the inventive concepts, conductive posts 530 for electrical connection of the third semiconductor chip 300 may be formed through a plating process using the sacrificial layer 1010. Accordingly, a plurality of conductive posts 530 may be formed at once through one process, and the semiconductor package manufacturing process may be simplified. Additionally, in the case of the second semiconductor chips 200 stacked on the third semiconductor chip 300, connection wires 520 for electrical connection of the second semiconductor chips 200 may be formed through wire bonding. The second semiconductor chips 200 may be electrically connected using thin connection wires 520, and a semiconductor package with improved integration may be provided.

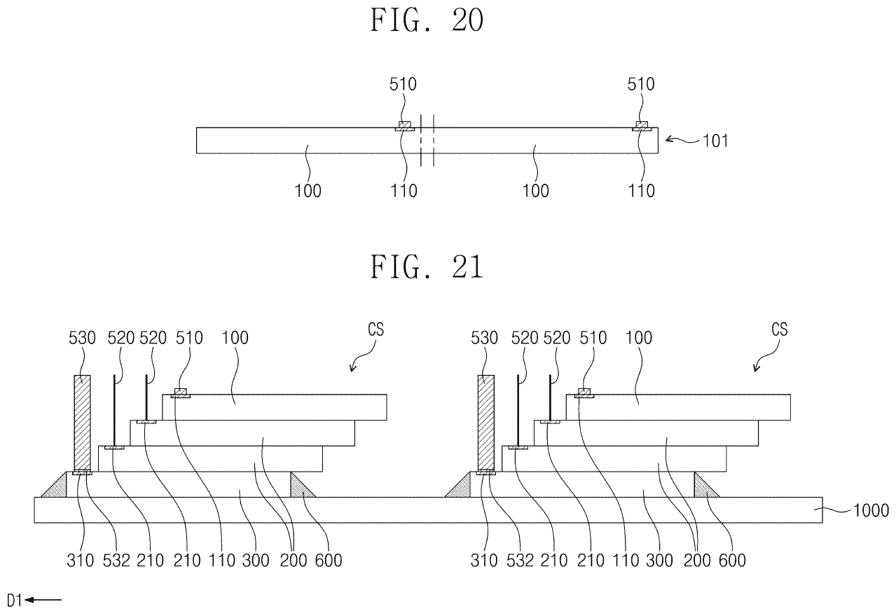

Referring to FIG. 20, first semiconductor chips 100 may be formed on a semiconductor wafer 101. For example, an integrated circuit such as a transistor may be formed on one side of the semiconductor wafer 101, and wiring and first chip pads 110 connected to the integrated circuit may be formed.

Thereafter, conductive bumps 510 may be formed on the first chip pads 110. For example, after forming a mask layer exposing the first chip pads 110 on the semiconductor wafer 101, the first chip pads 110 may be filled with a conductive material to form the conductive bumps 510.

Afterward, the semiconductor wafer 101 may be cut along a sawing line of the semiconductor wafer 101 to separate the first semiconductor chips 100 from each other.

According to various example embodiments of the inventive concepts, the conductive bumps 510 for electrical connection of the uppermost first semiconductor chips 100 stacked on the carrier substrate 1000 may be formed in a step of forming the first semiconductor chips 100 on the semiconductor wafer 101. Accordingly, there is no need to form terminals for electrical connection on the stacked first semiconductor chips 100, and thus difficulty of the semiconductor package manufacturing process may be reduced.

Referring to FIG. 21, first semiconductor chips 100 may be stacked on second semiconductor chips 200. Based on one third semiconductor chip 300, the first semiconductor chip 100 may be attached to the uppermost second semiconductor chip 200 using an adhesive layer. The first semiconductor chips 100 may be arranged face up. That is, the back surfaces of the first semiconductor chips 100 may face the carrier substrate 1000, and the first chip pads 110 and conductive bumps 510 of the first semiconductor chips 100 may face the carrier substrate 1000. The uppermost second semiconductor chips 200 and the first semiconductor chips 100 may be stacked to be shifted to each other in a direction opposite to the first direction D1 of the carrier substrate 1000 so that the second chip pads 210 are exposed. The first, second, and third semiconductor chips 100, 200, and 300 stacked together may form the chip stack CS described with reference to FIG. 1.

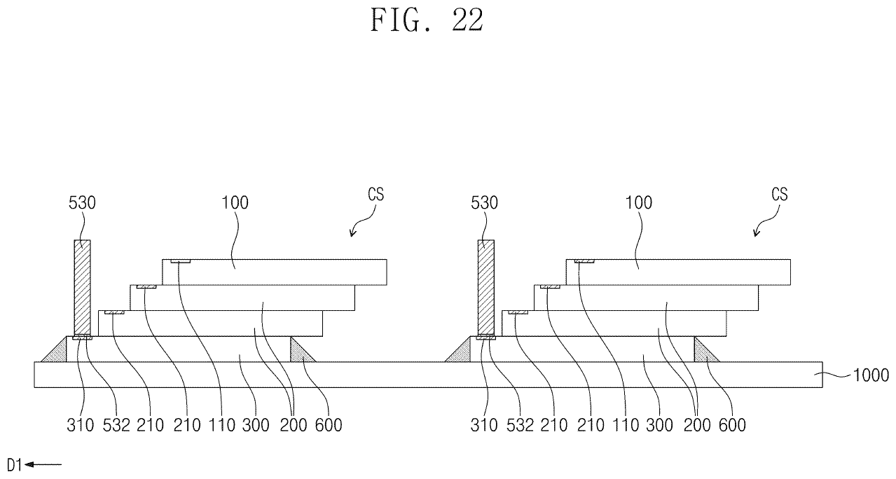

According to other example embodiments, as shown in FIG. 22, the first semiconductor chips 100 may be stacked on the second semiconductor chips 200 before the connection wires 520 are formed. At this time, the first semiconductor chips 100 may not have conductive bumps 510.

Thereafter, as described with reference to FIG. 19, connection wires 520 may be formed on the second chip pads 210 of the second semiconductor chips 200. In this case, the semiconductor package described with reference to FIG. 4 may be manufactured.

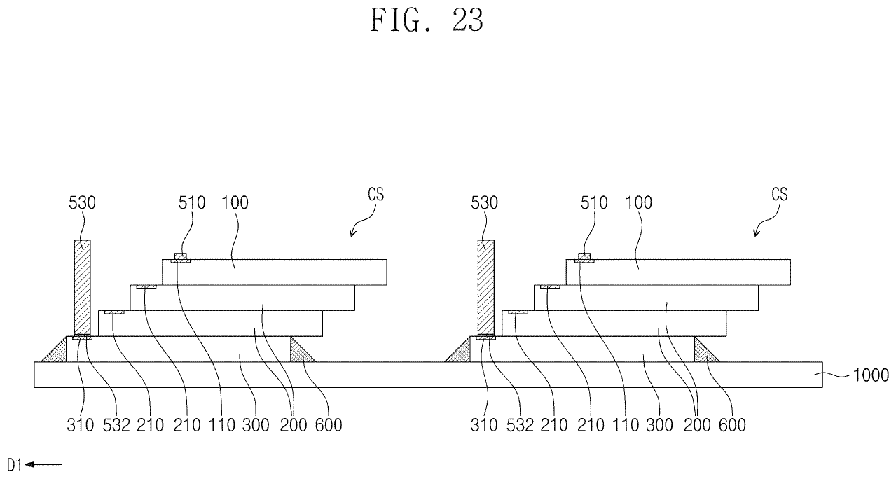

According to still other example embodiments, as shown in FIG. 23, the first semiconductor chips 100 may be stacked on the second semiconductor chips 200 before the connection wires 520 are formed. At this time, the first semiconductor chips 100 may have conductive bumps 510.

Thereafter, as described with reference to FIG. 19, the connection wires 520 may be formed on the second chip pads 210 of the second semiconductor chips 200. Hereinafter, the description will continue based on the results of FIG. 21.

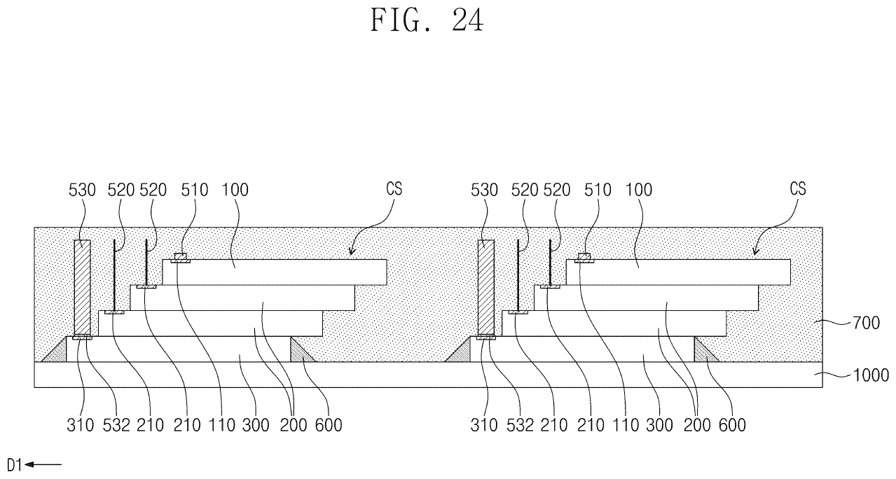

Referring to FIG. 24, a molding layer 700 may be formed on the carrier substrate 1000. For example, a molding material may be applied to bury the chip stacks CS, the conductive posts 530, the connection wires 520, and the conductive bumps 510 on the upper surface of the carrier substrate 1000. The molding material may be cured to form the molding layer 700. The molding material may include, for example, epoxy molding compound (EMC). However, example embodiments are not limited thereto.

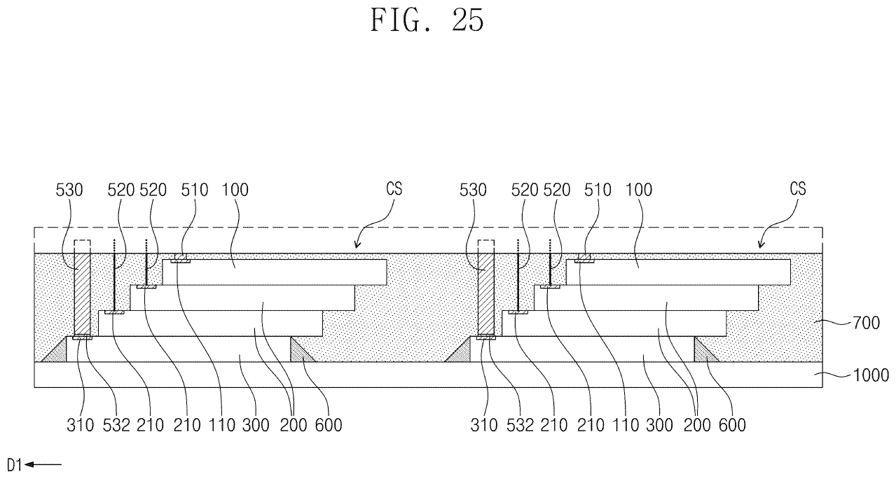

Referring to FIG. 25, a thinning process may be performed on the molding layer 700. The thinning process may include an etching process, a chemical mechanical polishing (CMP), or grinding process. However, example embodiments are not limited thereto. An upper surface of the molding layer 700 may be lowered through the thinning process. The thinning process may be performed until upper surfaces of the conductive posts 530, upper surfaces of the connection wires 520, and upper surfaces of the conductive bumps 510 are exposed. During the thinning process, an upper portion of the conductive posts 530, the upper portion of the connection wires 520, and the upper portion of the conductive bumps 510 may be removed.

In the case of FIG. 22, the thinning process may be performed until the upper surfaces of the conductive posts 530, the upper surfaces of the connection wires 520, and the upper surfaces of the first chip pads 110 are exposed.

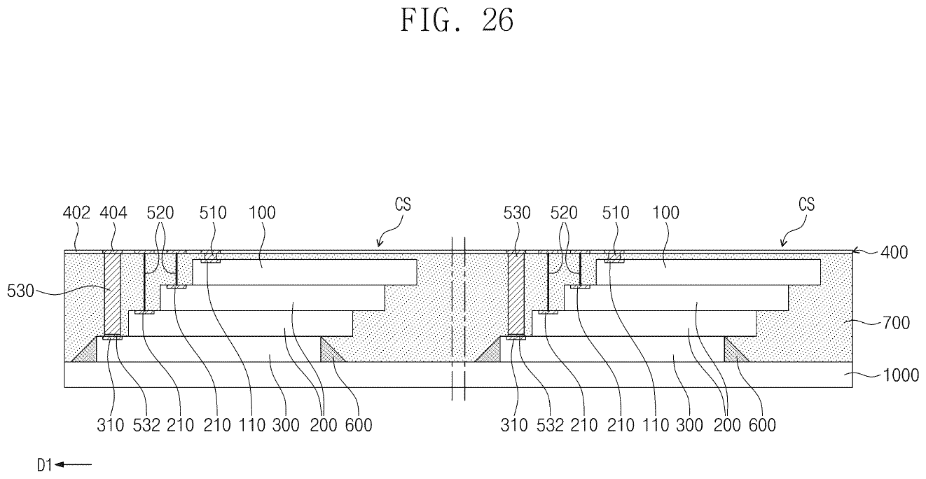

Referring to FIG. 26, a pad layer 400 may be formed on the molding layer 700.

An insulating layer may be formed on the molding layer 700. The insulating layer may include insulating polymer or photoimageable dielectric. Thereafter, the insulating layer may be patterned to form an insulating pattern 402 having openings exposing the upper surfaces of the conductive posts 530, the upper surfaces of the connection wires 520, and the upper surfaces of the conductive bumps 510.

Thereafter, the openings may be filled with a conductive material to form pads 404.

According to other example embodiments, the package substrate 900 described with reference to FIG. 6, rather than the pad layer 400, may be formed on the molding layer 700.

The carrier substrate 1000 may be removed.

A sawing process may be performed on the pad layer 400 and the molding layer 700 along the sawing line SL, and thus a semiconductor package may be manufactured to a required size.

In the semiconductor package according to various example embodiments of the inventive concepts, the semiconductor chips positioned at the middle level of the chip stack may be connected to the pad layer using the connection wires. At this time, the lowest semiconductor chip of the chip stack may be connected to and supported by the pad layer using the conductive bumps, and the uppermost semiconductor chip of the chip stack may be connected to and supported by the pad layer using the conductive posts. That is, the chip stack may be firmly supported by the conductive bumps and the conductive posts, and structural stability may be improved. Additionally, the intermediate semiconductor chips may be connected to the pad layer using the thin connection wires, thereby providing the semiconductor package with improved integration.

In the method of manufacturing the semiconductor package according to various example embodiments of the inventive concepts, the third semiconductor chips and the carrier substrate may have the step depending on the shape of the third semiconductor chips. However, as the insulating patterns having the inclined surfaces are formed on the side surfaces of the third semiconductor chips, it may be easy to form the seed layer on the carrier substrate and the third semiconductor chips. Accordingly, the method of manufacturing the semiconductor package with less occurrence of defects may be provided.

Additionally, the conductive posts for electrical connection to the third semiconductor chip may be formed simultaneously through the single plating process, thereby simplifying the manufacturing process of the semiconductor package. The second semiconductor chips may be electrically connected using the thin connection wires, thereby providing the semiconductor package with the improved integration. The conductive bumps for electrical connection of the first semiconductor chip may be formed in the step of forming the first semiconductor chip on the semiconductor wafer. Accordingly, there is no need to perform an additional process of forming terminals for electrical connection while the first semiconductor chip is stacked on the second semiconductor chips, thereby reducing the difficulty of the semiconductor package manufacturing process.

While various example embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A semiconductor package comprising:
a first semiconductor chip including a first chip pad on an upper surface of the first semiconductor chip;
a second semiconductor chip stacked on the first semiconductor chip and including a second chip pad on an upper surface of the second semiconductor chip;
an insulating pattern covering a side surface of the first semiconductor chip and having a width that decreases from a lower surface of the first semiconductor chip toward the upper surface of the first semiconductor chip;
a conductive post at one side of the second semiconductor chip, the conductive post connected to the first chip pad and extending in a direction perpendicular to the upper surface of the first semiconductor chip;
a seed pattern between the first chip pad and the conductive post;
a first connection wire connected to the second chip pad and extending in a direction perpendicular to the upper surface of the second semiconductor chip; and
a molding layer surrounding the first semiconductor chip, the second semiconductor chip, the conductive post, and the first connection wire,
wherein an upper surface of the conductive post and an upper end of the first connection wire are exposed on an upper surface of the molding layer.

2. The semiconductor package of claim 1, wherein
the insulating pattern covers the side surface of the first semiconductor chip,
the uppermost end of the insulating pattern is at a same vertical level as the upper surface of the first semiconductor chip, and
a lower surface of the insulating pattern is coplanar with the lower surface of the first semiconductor chip.

3. The semiconductor package of claim 2, wherein the uppermost end of the insulating pattern is in contact with the uppermost edge of the first semiconductor chip.

4. The semiconductor package of claim 1, wherein a lower surface of the molding layer, the lower surface of the first semiconductor chip, and a lower surface of the insulating pattern are coplanar.

5. The semiconductor package of claim 1, wherein the molding layer covers at least a portion of the upper surface of the second semiconductor chip.

6. The semiconductor package of claim 1, wherein a width of the seed pattern is equal to a width of the conductive post.

7. The semiconductor package of claim 1, wherein the first connection wire includes:
a bonding portion adhered to the second chip pad, and
a wire loop extending from the bonding portion, and
wherein a width of the bonding portion is greater than a width of the wire loop.

8. The semiconductor package of claim 1, further comprising:
a protective layer covering the lower surface of the first semiconductor chip, a lower surface of the insulating pattern, and a lower surface of the molding layer.

9. The semiconductor package of claim 1, further comprising:
a redistribution substrate on the upper surface of the molding layer,
wherein the redistribution substrate includes a substrate insulating pattern covering the molding layer, and a substrate wiring pattern in the substrate insulating pattern, and
wherein the substrate wiring pattern penetrates the substrate insulation pattern and is connected to the upper surface of the conductive post and the upper end of the first connection wire.

10. The semiconductor package of claim 1, further comprising:
external pads on the upper surface of the molding layer, and external terminals connected to the external pads,
wherein the upper surface of the conductive post and the upper end of the first connection wire are connected to lower surfaces of the external pads.

11. The semiconductor package of claim 1, further comprising:
a third semiconductor chip stacked on the second semiconductor chip and including a third chip pad on an upper surface of the third semiconductor chip;
a fourth semiconductor chip stacked on the third semiconductor chip and including a fourth chip pad on an upper surface of the fourth semiconductor chip;
a second connection wire connected to the third chip pad at one side of the fourth semiconductor chip, and the second connection wire extending in a direction perpendicular to the upper surface of the third semiconductor chip; and
a conductive bump connected to the fourth chip pad,
wherein the first connection wire is at one side of the third semiconductor chip,
wherein the molding layer surrounds the first semiconductor chip, the second semiconductor chip, the third semiconductor chip, the fourth semiconductor chip, the conductive post, the first connection wire, the second connection wire, and the conductive bump, and
wherein an upper end of the second connection wire and an upper surface of the conductive bump are exposed on the upper surface of the molding layer.

12. A semiconductor package comprising:
a package substrate;
a chip stack including semiconductor chips stacked on the package substrate;
a molding layer surrounding the chip stack on the package substrate; and
external terminals connected to a lower surface of the package substrate,
wherein the chip stack is spaced vertically from an upper surface of the package substrate,
wherein each of the semiconductor chips includes a chip pad on a lower surface thereof,
wherein the chip stack includes a first semiconductor chip as the lowermost one of the semiconductor chips, a second semiconductor chip as the uppermost one of the semiconductor chips, and a third semiconductor chip between the first semiconductor chip and the second semiconductor chip,
wherein the first semiconductor chip is electrically connected to the package substrate through a conductive bump that vertically penetrates the molding layer and connects a first substrate pad of the package substrate and the chip pad of the first semiconductor chip,
wherein the second semiconductor chip is electrically connected to the package substrate through a conductive post that vertically penetrates the molding layer and connects a second substrate pad of the package substrate and the chip pad of the second semiconductor chip, and
wherein the third semiconductor chip is electrically connected to the package substrate through at least one connection wire that vertically penetrates the molding layer and respectively connects a third substrate pad of the package substrate and the chip pad of the third semiconductor chip.

13. The semiconductor package of claim 12, further comprising:
an insulating pattern entirely covering a side surface of the second semiconductor chip,
wherein the insulating pattern has an inclined surface connected to a lower edge of the second semiconductor chip, and
wherein an upper surface of the insulating pattern is coplanar with an upper surface of the second semiconductor chip.

14. The semiconductor package of claim 13, wherein a width of the insulating pattern decreases from an upper surface of the second semiconductor chip toward a lower surface of the second semiconductor chip.

15. The semiconductor package of claim 12, wherein an upper surface of the molding layer is coplanar with an upper surface of the second semiconductor chip.

16. The semiconductor package of claim 12, wherein the molding layer fills a space between a lower surface of the first semiconductor chip and the upper surface of the package substrate.

17. The semiconductor package of claim 12, further comprising:
a seed pattern between the chip pad of the second semiconductor chip and the conductive post,
wherein a width of the seed pattern is equal to a width of the conductive post.

18. A method of manufacturing a semiconductor package, the method comprising:
attaching a first semiconductor chip to a carrier substrate, the first semiconductor chip including a first chip pad on an upper surface thereof;
forming an insulating pattern surrounding the first semiconductor chip on the carrier substrate, the insulating pattern including an inclined surface connecting an upper surface of the carrier substrate and an upper surface of the first semiconductor chip;
forming a seed layer covering the upper surface of the carrier substrate, the inclined surface of the insulating pattern, and the upper surface of the first semiconductor chip;
forming a mask layer covering the first semiconductor chip and the seed layer on the carrier substrate, the mask layer including a vertical hole exposing the seed layer above the first chip pad;
filling the vertical hole with a conductive material to form a conductive post;
removing the mask layer;
selectively removing the seed layer using the conductive post as a mask;
attaching a second semiconductor chip on the first semiconductor chip such that the second semiconductor chip is spaced horizontally from the first chip pad, the second semiconductor chip including a second chip pad on an upper surface of the second semiconductor chip;
bonding a connection wire extending perpendicularly to the second chip pad using a bonding device;
forming a molding layer covering the first semiconductor chip, the second semiconductor chip, the conductive post, and the connection wire on the carrier substrate; and
performing a thinning process on the molding layer,
wherein after the thinning process, an upper surface of the conductive post and the uppermost end of the connection wire are exposed on an upper surface of the molding layer.

19. The method of claim 18, wherein the bonding of the connection wire on the second chip pad using the bonding device includes:
lowering the bonding device to form a bonding portion on the second chip pad; and
moving the bonding device away from the bonding portion to form the connection wire.

20. The method of claim 18, further comprising:
before the forming of the molding layer,
forming third semiconductor chips on a semiconductor wafer, each of the third semiconductor chips including third chip pads on upper surfaces of each of the third semiconductor chips respectively;
forming conductive bumps on the third chip pads;
cutting the semiconductor wafer to separate the third semiconductor chips; and
attaching one of the third semiconductor chips to the second semiconductor chip so that the one of the third semiconductor chips is horizontally spaced from the second chip pad,
wherein an upper surface of the conductive bumps are exposed on the upper surface of the molding layer after the thinning process.
